(19) United States
(12) Patent Application Publication
(10) Pub. No.: US 2025/0280701 A1
(43) Pub. Date: Sep. 4, 2025

(54) DISPLAY DEVICE INCLUDING AN AUXILIARY ELECTRODE AND ELECTRONIC DEVICE INCLUDING THE SAME

(71) Applicant: SAMSUNG DISPLAY CO., LTD., YONGIN-SI (KR)

(72) Inventors: SEUNGRAE KIM, Yongin-si (KR); JAEHYUN LEE, Yongin-si (KR); YEEUN KANG, Yongin-si (KR); SUNGWON KIM, Yongin-si (KR); SEOHEE LEE, Yongin-si (KR)

(21) Appl. No.: 19/061,032

(22) Filed: Feb. 24, 2025

(30) Foreign Application Priority Data
Mar. 4, 2024 (KR) 10-2024-0030614

(51) Int. Cl. H10K 59/80; H10K 59/12; H10K 59/122; H10K 59/123; H10K 59/124; H10K 59/131

(52) U.S. Cl. CPC H10K 59/80522; H10K 59/1201; H10K 59/122; H10K 59/123; H10K 59/131; H10K 59/80521; H10K 59/124

(57) ABSTRACT

A display device includes: an auxiliary power line disposed in a display area on a substrate and electrically connected to a voltage supply part, an organic insulating layer disposed on the auxiliary power line, a pixel electrode disposed in the display area on the organic insulating layer, an auxiliary electrode disposed in a same layer as the pixel electrode in the display area and connected to the auxiliary power line, a light-emitting layer disposed in the display area and on the pixel electrode and the auxiliary electrode, and a common electrode disposed in the display area and on the light-emitting layer and connected to the auxiliary electrode through an auxiliary electrode contact hole, the auxiliary electrode contact hole penetrating a portion of the light-emitting layer and overlapping the organic insulating layer in a plan view.

### CROSS-REFERENCE TO RELATED APPLICATION

This application claims priority under 35 U.S.C. § 119 to Korean Patent Application No. 10-2024-0030614, filed on Mar. 4, 2024, in the Korean Intellectual Property Office (KIPO), the entire contents of which are hereby incorporated by reference.

### BACKGROUND

### 1. Technical Field

The present application is related to a display device. More particularly, the present application is related to the display device including an auxiliary electrode.

### 2. Discussion of Related Art

As information technology develops, the importance of display devices is increasing. The display devices may be a means for communicating information to users. Accordingly, the use of display devices such as a liquid crystal display device, an organic light emitting display device, a plasma display device, and the like is increasing.

The display device may include a plurality of light-emitting elements, and the plurality of light-emitting elements include a common electrode as a plate electrode. As the size of the display device increases, the quality of the display device may deteriorate due to a drop in voltage provided to the common electrode.

### SUMMARY

Embodiments provide a display device with improved display quality.

Embodiments provide an electronic device including the display device.

A display device according to embodiments of the present disclosure includes an auxiliary power line disposed in a display area on a substrate and to which a power supply voltage is applied, an organic insulating layer disposed on the auxiliary power line, a pixel electrode disposed in the display area on the organic insulating layer, an auxiliary electrode disposed in a same layer as the pixel electrode in the display area and connected to the auxiliary power line, a light-emitting layer disposed in the display area and on the pixel electrode and the auxiliary electrode, and a common electrode disposed in the display area and on the light-emitting layer and connected to the auxiliary electrode through an auxiliary electrode contact hole, the auxiliary electrode contact hole penetrating a portion of the light-emitting layer and the auxiliary electrode contact hole overlapping the organic insulating layer in a plan view.

In an embodiment, a portion of the auxiliary electrode exposed by the auxiliary electrode contact hole penetrating the portion of the light-emitting layer may be spaced apart from the auxiliary power line when viewed a cross-section.

In an embodiment, the display device may further include a protective layer disposed between the substrate and the organic insulating layer and covering the auxiliary power line. The auxiliary electrode may be connected to the auxiliary power line through a second via contact hole penetrating a portion of the organic insulating layer and a second contact hole penetrating a portion of the protective layer and overlapping the second via contact hole.

In an embodiment, the auxiliary electrode contact hole penetrating the portion of the light-emitting layer may overlap the protective layer in the plan view.

In an embodiment, the display device may further include a pixel defining layer disposed on the organic insulating layer and exposing at least a portion of the pixel electrode and a portion of the auxiliary electrode. The pixel defining layer may fill the second via contact hole and the second contact hole penetrating the portion of the protective layer.

In an embodiment, a first side surface of the protective layer exposed by the second contact hole penetrating the portion of the protective layer may protrude more in a direction parallel to the substrate than a second side surface of the organic insulating layer exposed by the second via contact hole.

In an embodiment, the display device may further include an active layer disposed in the display area on the substrate, a gate electrode disposed on the active layer and overlapping a channel region of the active layer, a first electrode connected to a source region of the active layer, and a second electrode disposed in a same layer as the first electrode and connected to a drain region of the active layer.

In an embodiment, the auxiliary power line may be disposed in a same layer as the first electrode and the second electrode.

In an embodiment, the auxiliary power line may be disposed in a same layer as the gate electrode.

In an embodiment, an upper surface of the organic insulating layer may include a depressed portion depressed toward the auxiliary power line, and the depressed portion may overlap the auxiliary electrode contact hole penetrating the portion of the light-emitting layer in the plan view.

A display device according to embodiments of the present disclosure includes an auxiliary power line disposed in a display area on a substrate and electrically connected to a voltage supply part, an organic insulating layer disposed on the auxiliary power line, a pixel electrode disposed in the display area on the organic insulating layer, an auxiliary electrode disposed in a same layer as the pixel electrode in the display area and connected to the auxiliary power line, a light-emitting layer disposed in the display area and on the pixel electrode and the auxiliary electrode, a common electrode disposed in the display area the display area and on the light-emitting layer and connected to the auxiliary electrode through an auxiliary contact hole penetrating a portion of the light-emitting layer, and a pixel defining layer disposed on the organic insulating layer, exposing at least a portion of the pixel electrode and at least a portion of the auxiliary electrode, and extending to an inside of a third via contact hole, the third via contact hole penetrating a portion of the organic insulating layer and overlapping the auxiliary contact hole in a plan view.

In an embodiment, the display device may further include a protective layer covering the auxiliary power line between the substrate and the organic insulating layer. The auxiliary electrode may be connected to the auxiliary power line through the third via contact hole and a second via contact hole penetrating a portion of the organic insulating layer, and wherein a second contact hole may penetrate a portion of the protective layer and expose the second via contact hole, and a third contact hole may penetrate a portion of the protective layer and expose the third via contact hole.

In an embodiment, the pixel defining layer may extend to an inside of the third via contact hole and the third contact hole.

In an embodiment, the pixel defining layer may expose at least a portion of the auxiliary electrode overlapping the third contact hole in a plan view.

In an embodiment, the pixel defining layer may fill the second via contact hole and the second contact hole.

In an embodiment, a first side surface of the protective layer exposed by the third contact hole may protrude further in a direction parallel to the substrate than a second side surface of the organic insulating layer exposed by the third via contact hole.

In an embodiment, a first side surface of the protective layer exposed by the second contact hole may protrude further in a direction parallel to the substrate than a second side surface of the organic insulating layer exposed by the second via contact hole.

In an embodiment, a portion of the auxiliary electrode exposed by the auxiliary electrode contact hole penetrating the portion of the light-emitting layer may be spaced apart from the auxiliary power line when viewed a cross-section.

In an embodiment, the display device may further include a protective layer disposed between the substrate and the organic insulating layer and covering the auxiliary power line. The auxiliary electrode may be connected to the auxiliary power line through a second via contact hole penetrating a portion of the organic insulating layer and a second contact hole penetrating a portion of the protective layer and overlapping the second via contact hole.

An electronic device according to embodiments of the present disclosure includes a display device includes: an auxiliary power line disposed in a display area on a substrate and electrically connected to a voltage supply part, an organic insulating layer disposed on the auxiliary power line, a pixel electrode disposed in the display area on the organic insulating layer, an auxiliary electrode disposed in a same layer as the pixel electrode in the display area and connected to the auxiliary power line, a light-emitting layer disposed in the display area and on the pixel electrode and the auxiliary electrode, and a common electrode disposed on the entire surface of the display area on the light-emitting layer and connected to the auxiliary electrode through an auxiliary electrode contact hole, the auxiliary electrode contact hole penetrating a portion of the light-emitting layer and overlapping the organic insulating layer in a plan view, and a processor which controls the display device.

In a display device according to an embodiment of the present disclosure, a common electrode may be connected to an auxiliary electrode to which a power supply voltage may be applied through a contact hole penetrating a portion of a light-emitting layer and overlapping an organic insulating layer in a plan view. The auxiliary electrode may be disposed in the same layer as a pixel electrode. Accordingly, disconnection of the common electrode caused by a protrusion of a protective layer may be prevented. In addition, voltage drop in the power supply voltage provided to the common electrode may be prevented. For example, the power supply voltage may be reliably provided to the common electrode through the auxiliary electrode in the contact area.

### BRIEF DESCRIPTION OF THE DRAWINGS

Illustrative, non-limiting embodiments will be more clearly understood from the following detailed description in conjunction with the accompanying drawings.

FIG. 1 is a plan view showing a display device according to an embodiment of the present disclosure.

FIG. 2 is a block diagram schematically showing the display device of FIG. 1.

FIG. 3 is a circuit diagram illustrating a pixel included in the display device of FIG. 1.

FIG. 4 is a cross-sectional view taken along line I-I′ of FIG. 1.

FIGS. 5, 6, 7, 8, 9, 10, 11, 12, 13, and 14 are cross-sectional views for explaining a method for manufacturing the display device of FIG. 4.

FIG. 15 is a cross-sectional view showing a display device according to an embodiment of the present disclosure.

FIG. 16 is a cross-sectional view showing a display device according to an embodiment of the present disclosure.

FIG. 17 is a block diagram showing an electronic device including the display device of FIG. 1.

FIG. 18 is a view illustrating an example in which the electronic device of FIG. 17 is implemented as a television.

### DETAILED DESCRIPTION

Hereinafter, a display device according to embodiments of the present disclosure will be explained in detail with reference to the accompanying drawings. Inventive concepts may be implemented in various modifications and have various forms. It is to be understood, however, that the inventive concepts are not intended to be limited to the particular forms disclosed, but on the contrary, is intended to cover all modifications, equivalents, and alternatives falling within the spirit and scope of the inventive concepts. The same reference numerals are used for the same components in the drawings, and redundant descriptions of the same components may be omitted or simplified. In the drawings, the thicknesses, the ratios, and the dimensions of the elements may be exaggerated for the effective description of the technical contents.

According to an embodiment, a structure of a display device inhibits or prevents a drop in voltage provided to a common electrode. The disconnection of the common electrode caused by a protrusion of a protective layer may be prevented. Accordingly, the common electrode may be easily connected to the auxiliary electrode through a contact hole penetrating the portion of a light-emitting layer. For example, the power supply voltage may be reliably provided to the common electrode through the auxiliary electrode in the contact area.

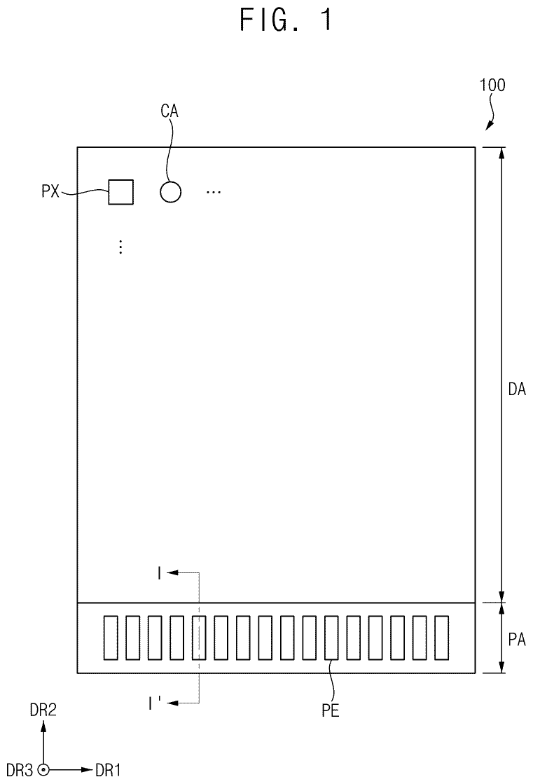

FIG. 1 is a plan view showing a display device according to an embodiment of the present disclosure.

In this specification, a plane may be defined along a first direction DR1 and a second direction DR2 intersecting the first direction DR1. For example, the first direction DR1 may be perpendicular to the second direction DR2. In addition, a third direction DR3 may be perpendicular to the plane formed by the first direction DR1 and the second direction DR2.

Referring to FIG. 1, the display device 100 according to an embodiment of the present disclosure may include a display area DA and a pad area PA. The display area DA may be an area that can display an image by generating light or adjusting the transmittance of light provided from an external light source.

A plurality of pixels PX may be arranged in the display area DA. For example, the plurality of pixels PX may be arranged in a matrix form along the first direction DR1 and the second direction DR2.

Each of the plurality of pixels PX may include a light-emitting element, which may generate light and a transistor that may drive the light-emitting element. For example, the light-emitting element may include an organic light emitting diode. Alternatively, the light-emitting element may include a nano light-emitting diode. The transistor may include a thin film transistor (TFT). An image may be displayed in the display area DA of the display device 100 through the plurality of pixels PX, each pixel PX including a light-emitting element and a transistor.

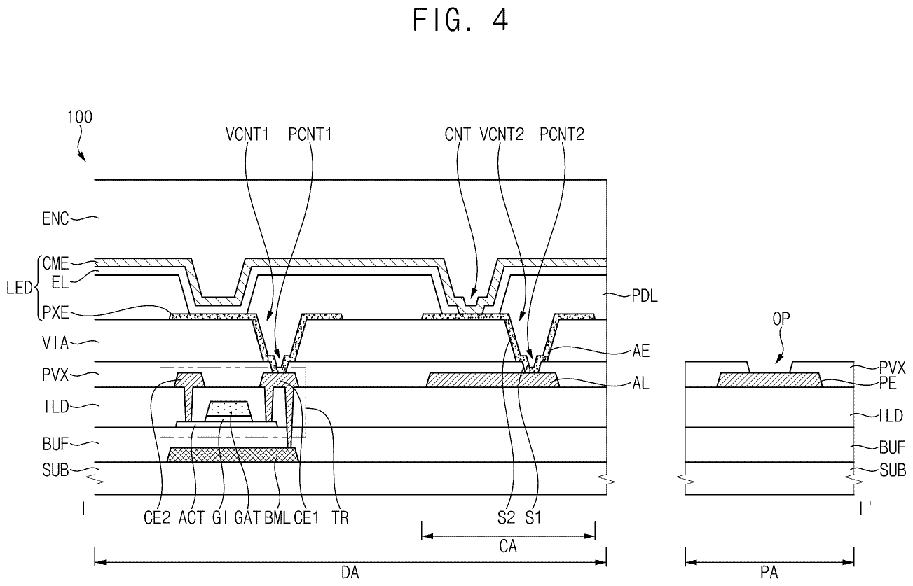

The display area DA may include a contact area CA. In the contact area CA, a common electrode (e.g., a common electrode CME of FIG. 4) of a light-emitting element (e.g., a light-emitting element LED of FIG. 4) and an auxiliary electrode (e.g., an auxiliary electrode AE of FIG. 4) may be in direct contact. Accordingly, the power supply voltage provided to the common electrode may be ensured. For example, the power supply voltage may be reliably provided to the common electrode CME through the auxiliary electrode AE in the contact area CA. The contact area CA may be provided in a plurality of the same.

The pad area PA may be disposed on at least one side of the display area DA. For example, the pad area PA may be disposed at an edge portion of the display area of under the display area DA. The pad area PA may be disposed separated from the display area DA by an intermediate area, such as a bending area.

A plurality of pad electrodes PE may be disposed in the pad area PA. The plurality of pad electrodes PE may be spaced apart from each other along the first direction DR1. The plurality of pad electrodes PE may be electrically connected to an external device. That is, the plurality of pad electrodes PE may electrically connect the external device and the plurality of pixels PX. Each of the plurality of pad electrodes PE may include metal, alloy, metal nitride, conductive metal oxide, or transparent conductive material. These materials can be used alone or in combination with each other.

The external device may be electrically connected to the display device 100 through a circuit board. For example, the circuit board may include a printed circuit board (PCB) or a flexible printed circuit board (FPCB). A first side of the circuit board may directly contact the plurality of pad electrodes PE, and a second side of the circuit board may directly contact the external device. The external device may provide at least one of a data signal, gate signal, a light-emitting control signal, an initialization voltage, or a power supply voltage to the display device 100. In addition, a driving integrated circuit (IC) may be mounted on the circuit board. Alternatively, the IC may be mounted on the display device 100.

In FIG. 1, a width of the pad area PA in the first direction DR1 is shown to be about equal to a width of the display area DA in the first direction DR1, but the present disclosure is not limited thereto. For example, the width of the pad area PA in the first direction DR1 may be smaller than, or larger than, the width of the display area DA in the first direction DR1.

The display device 100 may have a rectangular planar shape. However, the present disclosure is not limited to this, and the display device 100 may have various planar shapes (e.g., a rectangular planar shape with rounded corners).

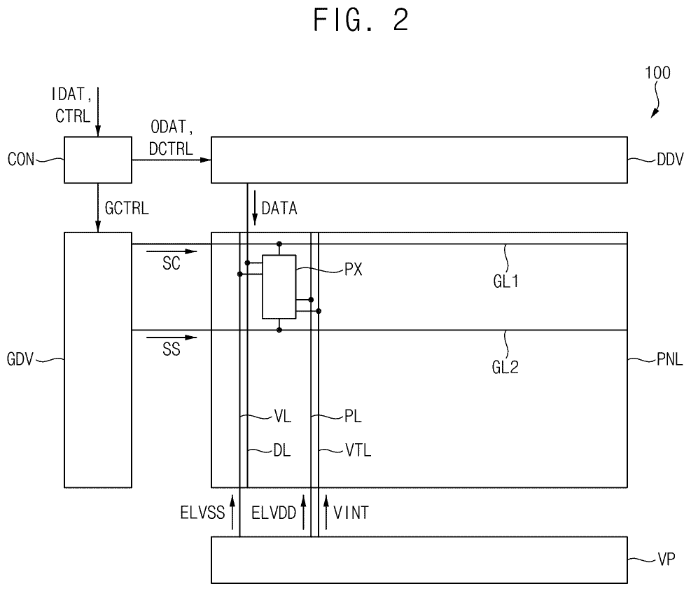

FIG. 2 is a block diagram schematically showing the display device of FIG. 1.

Referring to FIG. 2, the display device 100 according to an embodiment of the present disclosure may include a display panel PNL, a data driver DDV, a gate driver GDV, a control part CON, and a voltage supply part VP.

The display panel PNL may include the plurality of pixels PX.

Each pixel PX may receive a first gate signal SC through the first gate line GL1 and a second gate signal SS through the second gate line GL2. In addition, the pixel PX may receive a data voltage DATA through a data line DL and an initialization voltage VINT through an initialization voltage line VTL. The data voltage DATA may be written to each pixel PX in response to the first gate signal SC, and the initialization voltage VINT may be written to each pixel PX in response to the second gate signal SS.

The data driver DDV may generate the data voltage DATA based on an output image data ODAT and a data control signal DCTRL. For example, the data driver DDV may generate a data voltage DATA corresponding to the output image data ODAT and may output the data voltage DATA in response to the data control signal DCTRL. For example, the data control signal DCTRL may include at least one of an output data enable signal, a horizontal start signal, or a load signal.

The gate driver GDV may generate the first and second gate signals SC and SS based on a gate control signal GCTRL. For example, each of the first and second gate signals SC and SS may include a gate-on voltage, which may turn on the transistor and a gate-off voltage, which may turn off the transistor. For example, the gate control signal GCTRL may include at least one of a vertical start signal or a clock signal.

The control part CON may receive an input image data IDAT and a control signal CTRL. For example, the control part CON may receive the input image data IDAT and the control signal CTRL from an external host process (e.g., GPU). The input image data IDAT may be RGB data including red image data, green image data, and blue image data. The control signal CTRL may include at least one of a vertical synchronization signal, a horizontal synchronization signal, an input data enable signal, or a master clock signal. The control part CON may generate the gate control signal GCTRL, the data control signal DCTRL, and the output image data ODAT based on the input image data IDAT and the control signal CTRL.

The voltage supply part VP may provide a driving voltage ELVDD, a common voltage ELVSS, and the initialization voltage VINT to each pixel PX. The driving voltage ELVDD may be provided to each pixel PX through a driving line PL. A power supply line VL may transmit the common voltage ELVSS to a common electrode. For example, the common voltage ELVSS may be provided to each pixel PX through the power supply line VL and the common electrode (e.g., the common electrode CME of FIG. 4). In this specification, the common voltage ELVSS may be referred to as a power supply voltage.

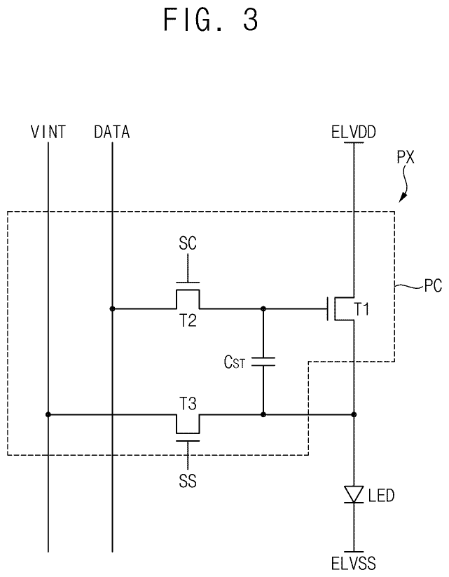

FIG. 3 is a circuit diagram illustrating a pixel included in the display device of FIG. 1.

Referring to FIG. 3, the pixel PX may include a pixel circuit PC and a light-emitting element LED. The pixel circuit PC may include a first transistor T1, a second transistor T2, a third transistor T3, and a storage capacitor CST. The pixel circuit PC may be electrically connected to the light-emitting element LED and may provide driving current to the light-emitting element LED.

The first transistor T1 may include a first terminal, a second terminal, and a gate terminal. The first terminal of the first transistor T1 may receive the driving voltage ELVDD. The second terminal of the first transistor T1 may be connected to the light-emitting element LED. The gate terminal of the first transistor T1 may be connected to the second transistor T2. The first transistor T1 may generate the driving current based on the driving voltage ELVDD and the data voltage DATA.

The second transistor T2 may include a first terminal, a second terminal, and a gate terminal. The first terminal of the second transistor T2 may receive the data voltage DATA. The second terminal of the second transistor T2 may be connected to the first transistor T1. The gate terminal of the second transistor T2 may receive the first gate signal SC. The second transistor T2 may transmit the data voltage DATA to the first transistor T1 in response to the first gate signal SC.

The third transistor T3 may include a first terminal, a second terminal, and a gate terminal. The first terminal of the third transistor T3 may be connected to the first transistor T1. The first terminal of the third transistor T3 may be connected to the second terminal of the first transistor T1 and the light-emitting element LED. The second terminal of the third transistor T3 may receive the initialization voltage VINT. The gate terminal of the third transistor T3 may receive the second gate signal SS. The third transistor T3 may transmit the initialization voltage VINT in response to the second gate signal SS.

The storage capacitor CST may include a first terminal and a second terminal. The first terminal of the storage capacitor CST may be connected to the gate terminal of the first transistor T1. The second terminal of the storage capacitor CST may be connected to the first terminal of the third transistor T3. The storage capacitor CST may maintain the voltage level of the gate terminal of the first transistor T1 during an inactivation period of the first gate signal SC.

The light-emitting element LED may include a first terminal and a second terminal. The first terminal of the light-emitting element LED may be connected to the second terminal of the first transistor T1. The second terminal of the light-emitting element LED may receive the common voltage ELVSS. The light-emitting element LED may emit light with luminance corresponding to the driving current. The light-emitting element LED may include an organic light-emitting element, which may use an organic material as a light-emitting layer, and an inorganic light-emitting element, which may use an inorganic material as a light-emitting layer.

In connection with FIG. 3, the case where the pixel circuit PC includes three transistors and one storage capacitor has been described, however embodiments of the present disclosure are not limited thereto. For example, the pixel circuit PC may include various numbers of transistors and various numbers of storage capacitors.

FIG. 4 is a cross-sectional view taken along line I-I′ of FIG. 1.

Referring to FIG. 4, the display device 100 according to an embodiment of the present disclosure may include a substrate SUB, a lower metal layer BML, a buffer layer BUF, a gate insulating layer GI, a transistor TR, an interlayer insulating layer ILD, an auxiliary power line AL, a pad electrode PE, a protective layer PVX, an organic insulating layer VIA, an auxiliary electrode AE, a pixel defining layer PDL, the light-emitting element LED, and an encapsulation layer ENC.

Here, the transistor TR may include an active layer ACT, a gate electrode GAT, a first electrode CE1, and a second electrode CE2, and the light-emitting element LED may include a pixel electrode PXE, a light-emitting layer EL, and the common electrode CME.

As described herein, the display device 100 may include the display area DA and the pad area PA. As the display device 100 includes the display area DA and the pad area PA, components included in the display device 100 (e.g., the substrate SUB and the like) may also include the display area DA and the pad area PA.

The substrate SUB may include a transparent material or an opaque material. The substrate SUB may be made of a transparent resin substrate. Examples of the transparent resin substrate may include a polyimide substrate. In this case, the substrate SUB may include a first organic layer, a first barrier layer, and a second organic layer. Alternatively, the substrate SUB may be, for example, a quartz substrate, a synthetic quartz substrate, a calcium fluoride substrate, a F-doped quartz substrate, a soda-lime glass substrate, or a non-alkali glass substrate. These materials can be used alone or in combination with each other.

The lower metal layer BML may be disposed in the display area DA on the substrate SUB. The lower metal layer BML may block external light incident on the transistor TR. For example, the lower metal layer BML may include metal, alloy, metal nitride, conductive metal oxide, or transparent conductive material. These materials can be used alone or in combination with each other.

The buffer layer BUF may be disposed on the substrate SUB. The buffer layer BUF may overlap the display area DA and the pad area PA. The buffer layer BUF may cover the lower metal layer BML in the display area DA. The buffer layer BUF may inhibit or prevent metal atoms or impurities from diffusing from the substrate SUB to the transistor TR. In addition, the buffer layer BUF may improve the flatness of the surface of the substrate SUB when the surface of the substrate SUB is not uniform. For example, the buffer layer BUF may cover the lower metal layer BML and have a substantially planar upper surface. For example, the buffer layer BUF may include an inorganic insulating material such as silicon oxide (SiOₓ), silicon nitride (SiNₓ), or silicon oxynitride (SiOₓN_{y}). These materials can be used alone or in combination with each other. Alternatively, the buffer layer BUF may be omitted.

The active layer ACT may be disposed in the display area DA on the buffer layer BUF. For example, the active layer ACT may include an inorganic semiconductor (e.g., amorphous silicon or polycrystalline silicon), an organic semiconductor, or a metal oxide semiconductor.

The metal oxide semiconductor may include a binary compound (ABₓ), a ternary compound (ABₓC_{y}), or a quaternary compound (ABₓC_{y}D_{z}) containing indium (In), zinc (Zn), gallium (Ga), tin (Sn), titanium (Ti), aluminum (Al), hafnium (Hf), zirconium (Zr), or magnesium (Mg). For example, the metal oxide semiconductor may include zinc oxide (ZnOₓ), gallium oxide (GaOₓ), tin oxide (SnOₓ), indium oxide (InOₓ), indium gallium oxide (IGO), indium zinc oxide (IZO), indium tin oxide. (ITO), indium zinc tin oxide (IZTO), or indium gallium zinc oxide (IGZO). These materials can be used alone or in combination with each other.

The active layer ACT may include a channel region, a source region, and a drain region. The channel region may be located between the source region and the drain region. The source region and the drain region may be doped with different impurities (e.g., P-type impurities or N-type impurities).

The gate insulating layer GI may be disposed on the active layer ACT. The gate insulating layer GI may include an inorganic material. For example, the gate insulating layer GI may include an inorganic material such as silicon oxide, silicon nitride, or silicon oxynitride. These materials can be used alone or in combination with each other. In an embodiment, the gate insulating layer GI may be patterned to overlap a portion of the active layer ACT in the plan view. In another embodiment, the gate insulating layer GI may span an entirety of the buffer layer BUF and cover the active layer ACT.

The gate electrode GAT may be disposed in the display area DA on the gate insulating layer GI. The gate electrode GAT may overlap the gate insulating layer GI in the plan view. In addition, the gate electrode GAT may overlap the channel region of the active layer ACT in the plan view. For example, the gate electrode GAT may include metal, alloy, metal nitride, conductive metal oxide, or transparent conductive material. These materials can be used alone or in combination with each other. In an embodiment, the gate electrode GAT may include a plurality of conductive layers.

The interlayer insulating layer ILD may be disposed on the buffer layer BUF, the active layer ACT, the gate insulating layer GI, and the gate electrode GAT. The interlayer insulating layer ILD may overlap the display area DA and the pad area PA. The interlayer insulating layer ILD may cover the active layer ACT, the gate insulating layer GI, and the gate electrode GAT in the display area DA. The interlayer dielectric layer ILD may have a substantially planar upper surface. The interlayer dielectric layer ILD may include an inorganic material such as a silicon compound. For example, the interlayer dielectric layer ILD may include an inorganic material such as silicon oxide, silicon nitride, or silicon oxynitride. These materials can be used alone or in combination with each other.

The first electrode CE1 and the second electrode CE2 may be disposed in the display area DA on the interlayer insulating layer ILD. The first electrode CE1 may be connected to the source region of the active layer ACT through a first contact hole penetrating a portion of the interlayer insulating layer ILD, and the second electrode CE2 may be connected to the drain region of the active layer ACT through a second contact hole penetrating another portion of the interlayer insulating layer ILD. In addition, the first electrode CE1 may be connected to the lower metal layer BML through a third contact hole penetrating a portion of the buffer layer BUF and the interlayer insulating layer ILD. In a case that the gate insulating layer GI spans an entirety of the buffer layer BUF, the first and second contact holes may penetrate the gate insulating layer GI, exposing the source region and the drain region of the active layer ACT. Further, the third contact hole may penetrate a portion of the gate insulating layer GI, the buffer layer BUF, and the interlayer insulating layer ILD.

Each of the first and second electrodes CE1 and CE2 may include metal, alloy, metal nitride, conductive metal oxide, or transparent conductive material. These materials can be used alone or in combination with each other. In an embodiment, each of the first and second electrodes CE1 and CE2 may include a plurality of conductive layers.

Accordingly, the transistor TR including the active layer ACT, the gate electrode GAT, the first electrode CE1, and the second electrode CE2 may be disposed in the display area DA on the substrate SUB. For example, the transistor TR may correspond to the first transistor T1 or the third transistor T3 shown in FIG. 3.

The auxiliary power line AL may be disposed in the display area DA on the interlayer insulating layer ILD. The auxiliary power line AL may be electrically connected to a power line (e.g., the power line VL of FIG. 2) and receive a common voltage (e.g., the common voltage ELVSS of FIG. 2). For example, the power line may be disposed in the same layer as the lower metal layer BML. In this case, an auxiliary pattern disposed in the same layer as the gate electrode GAT may be disposed between the power line and the auxiliary power line AL, and the auxiliary power line AL may be electrically connected to the power line through the auxiliary pattern. However, embodiments of the present disclosure are not limited thereto.

For example, the auxiliary power line AL may extend in a direction (e.g., the first direction DR1 or the second direction DR2 of FIG. 1). However, embodiments of the present disclosure are not limited thereto. In an embodiment, the auxiliary power line AL may include a plurality of conductive layers.

In an embodiment, the auxiliary power line AL may be disposed in the same layer as the first electrode CE1 and the second electrode CE2 and may include the same material. However, embodiments of the present disclosure are not limited to this, and in an embodiment, the auxiliary power line AL may be disposed in the same layer as the gate electrode GAT and may include the same material as the gate electrode GAT. In this case, the first electrode CE1 and the second electrode CE2 may be also disposed in the same layer as the gate electrode GAT and may include the same material as the gate electrode GAT.

The pad electrode PE may be disposed in the pad area PA on the interlayer insulating layer ILD. The pad electrode PE may be disposed in the same layer as the first electrode CE1, the second electrode CE2, and the auxiliary power line AL, and may include the same material as the first electrode CE1, the second electrode CE2, and the auxiliary power line AL. In an embodiment, the pad electrode PE may include a plurality of conductive layers.

The protective layer PVX may be disposed on the interlayer insulating layer ILD, the first electrode CE1, the second electrode CE2, the auxiliary power line AL, and the pad electrode PE. The protective layer PVX may cover the first electrode CE1, the second electrode CE2, and the auxiliary power line AL in the display area DA. The protective layer PVX may have a substantially planar upper surface. The protective layer PVX may include an inorganic material such as a silicon compound. The protective layer PVX may include an inorganic material such as silicon oxide, silicon nitride, or silicon oxynitride. These materials can be used alone or in combination with each other.

In an embodiment, in the display area DA, a first contact hole PCNT1 exposing at least a portion of the first electrode CE1 and a second contact hole PCNT2 exposing at least a portion of the auxiliary power line AL may be defined in the protective layer PVX. In other words, each of the first contact hole PCNT1 and the second contact hole PCNT1 may be defined by penetrating portions of the protective layer PVX.

In an embodiment, in the pad area PA, an opening OP exposing at least a portion of the pad electrode PE may be defined in the protective layer PVX. In other words, the opening OP may be defined by penetrating a portion of the protective layer PVX. The pad electrode PE may be electrically connected to the circuit board through the opening OP.

The organic insulating layer VIA may be disposed on the protective layer PVX. The organic insulating layer VIA may be disposed in the display area DA. and may be omitted from the pad area PA. In an embodiment, the organic insulating layer VIA may be formed in the display area DA and the pad area PA and removed from at least a portion the pad area PA to expose at least a portion of the opening OP and a portion of the pad electrode PE. The organic insulating layer VIA may include an organic insulating material such as polyimide resin, polyamide resin, siloxane resin, or epoxy resin. These materials can be used alone or in combination with each other.

In an embodiment, a first via contact hole VCNT1 connected to the first contact hole PCNT1 and exposing the first contact hole PCNT1 may be defined in the organic insulating layer VIA. The first via contact hole VCNT1 may expose at least a portion of the first electrode CE1 together with the first contact hole PCNT1. In other words, the first via contact hole VCNT1 may be defined by penetrating a portion of the organic insulating layer VIA.

Likewise, in an embodiment, a second via contact hole VCNT2 connected to the second contact hole PCNT2 and exposing the second contact hole PCNT2 may be defined in the organic insulating layer VIA. The second via contact hole VCNT2 may expose at least a portion of the auxiliary power line AL together with the second contact hole PCNT2. In other words, the second via contact hole VCNT2 may be defined by penetrating a portion of the organic insulating layer VIA.

In an embodiment, a first side surface S1 of the protective layer PVX exposed by the second contact hole PCNT2 may protrude further in a direction parallel to the substrate SUB than a second side surface S2 of the organic insulating layer VIA exposed by the second via contact hole VCNT2. For example, in a plan view, an upper portion of the second contact hole PCNT2 have a cross section that is smaller than a cross section of a lower portion of the second via contact hole VCNT2. For example, the second contact hole PCNT2 and the second contact hole VCNT2 may form a stepped sidewall. Likewise, a first side surface of the protective layer PVX exposed by the first contact hole PCNT1 may protrude further in a direction parallel to the substrate SUB than a second side surface of the organic insulating layer VIA exposed by the first via contact hole VCNT1. For example, in a plan view, an upper portion of the first contact hole PCNT1 have a cross section that is smaller than a cross section of a lower portion of the first via contact hole VCNT1. For example, the first contact hole PCNT1 and the first via contact hole VCNT1 may form a stepped sidewall. However, embodiments of the present disclosure are not limited thereto.

The pixel electrode PXE may be disposed in the display area DA on the organic insulating layer VIA. The pixel electrode PXE may be connected to the first electrode CE1 (or the second electrode CE2) through the first contact hole PCNT1 and the first via contact hole VCNT1. Specifically, the pixel electrode PXE may extend to the inside of each of the first contact hole PCNT1 and the first via contact hole VCNT1 and directly contact the first electrode CE1 (or the second electrode CE2). Accordingly, the pixel electrode PXE may be electrically connected to the transistor TR. The pixel electrodes PXE may include metal, alloy, metal nitride, conductive metal oxide, or transparent conductive material. These materials can be used alone or in combination with each other. The pixel electrode PXE may act as an anode.

The auxiliary electrode AE may be disposed in the display area DA on the organic insulating layer VIA. In an embodiment, the auxiliary electrode AE may be disposed in the same layer as the pixel electrode PXE and may include the same material as the pixel electrode PXE.

In an embodiment, the auxiliary electrode AE may be connected to the auxiliary power line AL through the second contact hole PCNT2 and the second via contact hole VCNT2. Specifically, the auxiliary electrode AE may extend to the inside of each of the second contact hole PCNT2 and the second via contact hole VCNT2 and directly contact the auxiliary power line AL. Accordingly, the auxiliary electrode AE may receive the common voltage through the auxiliary power line AL.

The pixel defining layer PDL may be disposed on the organic insulating layer VIA, the pixel electrode PXE, and the auxiliary electrode AE. The pixel defining layer PDL may be disposed in the display area DA and not in the pad area PA. The pixel defining layer PDL may expose at least a portion of each of the pixel electrode PXE and the auxiliary electrode AE. The pixel defining layer PDL may include inorganic materials and/or organic materials. For example, the pixel defining layer PDL may include an organic material such as epoxy resin, or siloxane resin. These materials can be used alone or in combination with each other. Alternatively, the pixel defining layer PDL may include an inorganic material and/or an organic material containing a light blocking material such as black pigment or black dye.

In an embodiment, the pixel defining layer PDL may be disposed in the first contact hole PCNT1 and the first via contact hole VCNT1. For example, the pixel defining layer PDL may fill the first contact hole PCNT1 and the first via contact hole VCNT1. In addition, the pixel defining layer PDL may be disposed in the second contact hole PCNT2 and the second via contact hole VCNT2. For example, the pixel defining layer PDL may fill the second contact hole PCNT2 and the second via contact hole VCNT2

The light-emitting layer EL may be disposed in the display area DA on the pixel defining layer PDL. Specifically, the light-emitting layer EL may be disposed on the entire surface of the display area DA. For example, the light-emitting layer EL may have a multilayer structure including a hole injection layer, a hole transport layer, an organic light-emitting layer, an electron transport layer, and an electron injection layer. In an embodiment, an auxiliary electrode contact hole CNT exposing at least a portion of the auxiliary electrode AE may be defined in the light-emitting layer EL in the contact area CA of the display area DA. That is, the auxiliary electrode contact hole CNT may be defined by penetrating a portion of the light emitting layer EL.

In an embodiment, the auxiliary electrode contact hole CNT may overlap the organic insulating layer VIA and the protective layer PVX in the plan view. That is, the portion of the auxiliary electrode AE exposed by the auxiliary electrode contact hole CNT may be spaced apart from the auxiliary power line AL when viewed a cross-section. In other words, each portion of the organic insulating layer VIA and the protective layer PVX located under the auxiliary electrode contact hole CNT may remain without being removed.

The common electrode CME may be disposed in the display area DA on the light-emitting layer EL. Specifically, the common electrode CME may be disposed on the entire surface of the display area DA. For example, the common electrode CME may include metal, alloy, metal nitride, conductive metal oxide, or transparent conductive material. These materials can be used alone or in combination with each other.

In an embodiment, in the contact area CA of the display area DA, the common electrode CME may be connected to the auxiliary electrode AE through the auxiliary electrode contact hole CNT. That is, the common electrode CME may directly contact the auxiliary electrode AE through the auxiliary electrode contact hole CNT. Accordingly, the common electrode CME may receive the common voltage through the auxiliary power line AL and the auxiliary electrode AE. In this case, a voltage drop of the common voltage (e.g., the power supply voltage) provided to the common electrode CME may be inhibited or prevented. The disconnection of the common electrode CME caused by a protrusion of the protective layer PVX may be prevented. Accordingly, the common electrode CME may be easily connected to the auxiliary electrode AE through the auxiliary electrode contact hole CNT penetrating the portion of the light-emitting layer. EML. For example, the power supply voltage may be reliably provided to the common electrode CME through the auxiliary electrode AE in the contact area CA.

Accordingly, the light-emitting element LED including the pixel electrode PXE, the light-emitting layer EL, and the common electrode CME may be disposed in the display area DA on the substrate SUB. The light-emitting element LED may be electrically connected to the transistor TR.

The encapsulation layer ENC may be disposed in the display area DA on the common electrode CME. The encapsulation layer ENC may cover the light emitting element LED. The encapsulation layer ENC may protect the light-emitting element LED from external impurities by sealing the display area DA. The encapsulation layer ENC may include at least one inorganic encapsulation layer and at least one organic encapsulation layer.

For example, a color conversion layer including quantum dots and a color filter layer on the color conversion layer may be additionally disposed on the encapsulation layer ENC. The color conversion layer may convert light emitted by the light emitting element LED having a specific color into another color. The color filter layer may selectively transmit light having a specific color. However, in embodiments of the present disclosure, the color conversion layer and the color filter layer may be disposed on layers other than the encapsulation layer ENC.

In the display device 100 according to an embodiment of the present disclosure, the common electrode CME may be connected to the auxiliary electrode AE through the auxiliary electrode contact hole CNT penetrating the portion of the light-emitting layer EL and overlapping the organic insulating layer VIA in the plan view. The auxiliary electrode AE may be located in the same layer as the pixel electrode PXE. Accordingly, disconnection of the common electrode CME, which may otherwise be caused by the protrusion of the protective layer PVX at the transistor TR, which may reduce a size of, or close the first contact hole PCNT1, may be prevented by the connection of the common electrode CME to the auxiliary electrode AE in the contact area CA, where the auxiliary electrode contact hole CNT penetrating the portion of the light-emitting layer EL is formed. In addition, the voltage drop in the power supply voltage provided to the common electrode CME may be prevented. For example, the power supply voltage provided to the common electrode CME may be ensured. For example, the power supply voltage may be reliably provided to the common electrode CME through the auxiliary electrode AE in the contact area CA.

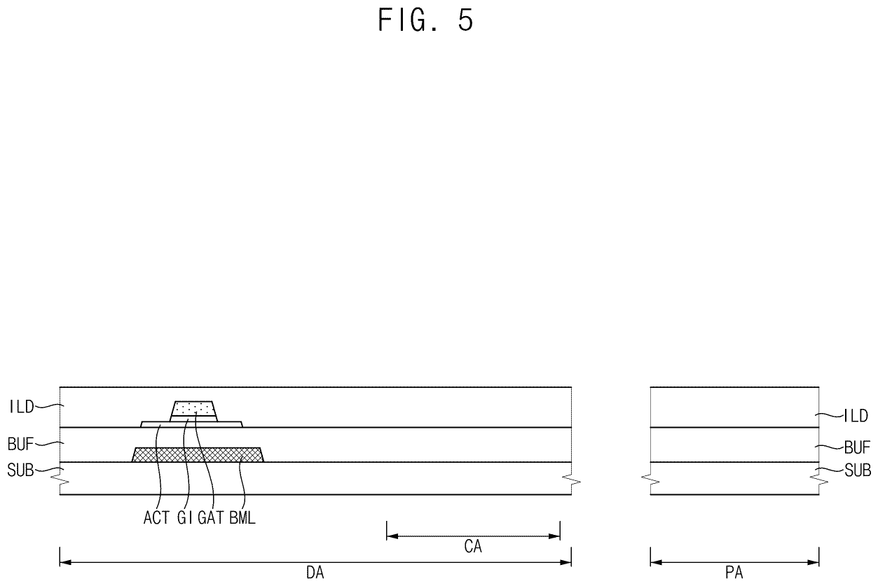

FIGS. 5, 6, 7, 8, 9, 10, 11, 12, 13, and 14 are cross-sectional views for explaining a method for manufacturing the display device of FIG. 4.

Referring to FIG. 5, the lower metal layer BML may be disposed in the display area DA on the substrate SUB. The substrate SUB may include a transparent material or an opaque material. The lower metal layer BML may be formed using metal, alloy, metal nitride, conductive metal oxide, or transparent conductive material.

The buffer layer BUF may be disposed on the substrate SUB. The buffer layer BUF may be formed in both the display area DA and the pad area PA. For example, the buffer layer BUF may be formed using an inorganic insulating material.

The active layer ACT may be disposed in the display area DA on the buffer layer BUF. For example, the active layer ACT may be formed using an inorganic semiconductor, an organic semiconductor, or a metal oxide semiconductor.

The gate insulating layer GI may be disposed in the display area DA on the active layer ACT. For example, the gate insulating layer GI may be formed using an inorganic insulating material. Specifically, after an inorganic layer is entirely formed on the buffer layer BUF and the active layer ACT, the gate insulating layer GI may be formed by patterning the inorganic layer. That is, the gate insulating layer GI may overlap a portion of the active layer ACT in the plan view.

The gate electrode GAT may be disposed in the display area DA on the gate insulating layer GI. For example, the gate electrode GAT may be formed using metal, alloy, metal nitride, conductive metal oxide, or transparent conductive material. The gate electrode GAT may overlap the gate insulating layer GI and a portion of the active layer ACT in the plan view.

Impurities may be doped into the portion of the active layer ACT using the gate electrode GAT as a mask. Accordingly, the active layer ACT may include a channel region which is not doped with impurities and a source region and drain region which are doped with impurities. The channel region may be disposed between the source region and the drain region.

The interlayer insulating layer ILD may be disposed on the buffer layer BUF, the gate insulating layer GI, and the gate electrode GAT. The interlayer insulating layer ILD may be formed in both the display area DA and the pad area PA. For example, the interlayer insulating layer ILD may be formed using an inorganic insulating material.

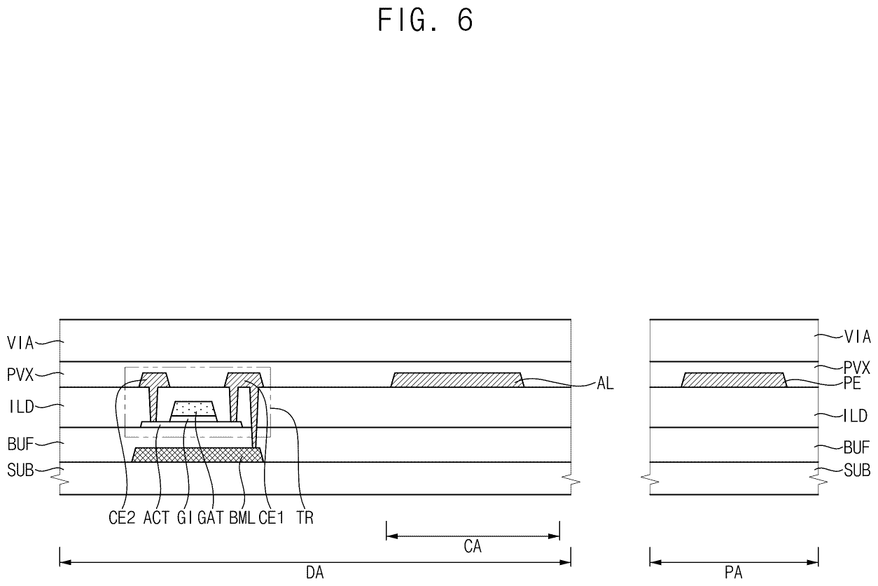

Referring to FIG. 6, a first contact hole exposing the source region of the active layer ACT may be formed by removing a portion of the interlayer insulating layer ILD. A second contact hole exposing the drain region of the active layer ACT may be formed by removing another portion of the interlayer insulating layer ILD. In addition, a third contact hole may be formed exposing a portion of the lower metal layer BML by removing a portion of the buffer layer BUF and the interlayer insulating layer ILD.

A metal layer may be disposed on the interlayer insulating layer ILD. The metal layer may be entirely formed on the interlayer insulating layer ILD. A metal layer may fill the first, second, and third contact holes. For example, the metal layer may be formed using metal, alloy, metal nitride, conductive metal oxide, or transparent conductive material.

The metal layer may be patterned to form the first electrode CE1, the second electrode CE2, and the auxiliary power line AL in the display area DA, and to form the pad electrode PE in the pad area PA. That is, the first electrode CE1, the second electrode CE2, the auxiliary power line AL, and the pad electrode PE may be formed simultaneously through the same process.

The first electrode CE1 may be connected to the source region of the active layer ACT through the first contact hole and to the lower metal layer BML through the third contact hole. The second electrode CE2 may be connected to the drain region of the active layer ACT through the second contact hole.

Accordingly, the transistor TR including the active layer ACT, the gate electrode GAT, the first electrode CE1, and the second electrode CE2 may be disposed in the display area DA on the substrate SUB.

The protective layer PVX may be disposed on the interlayer insulating layer ILD, the first electrode CE1, the second electrode CE2, the auxiliary power line AL, and the pad electrode PE. The protective layer PVX may be formed in both the display area DA and the pad area PA. For example, the protective layer PVX may be formed using an inorganic insulating material.

The organic insulating layer VIA may be disposed on the protective layer PVX. The organic insulating layer VIA may be formed in both the display area DA and the pad area PA. For example, the organic insulating layer VIA may be formed using an organic insulating material.

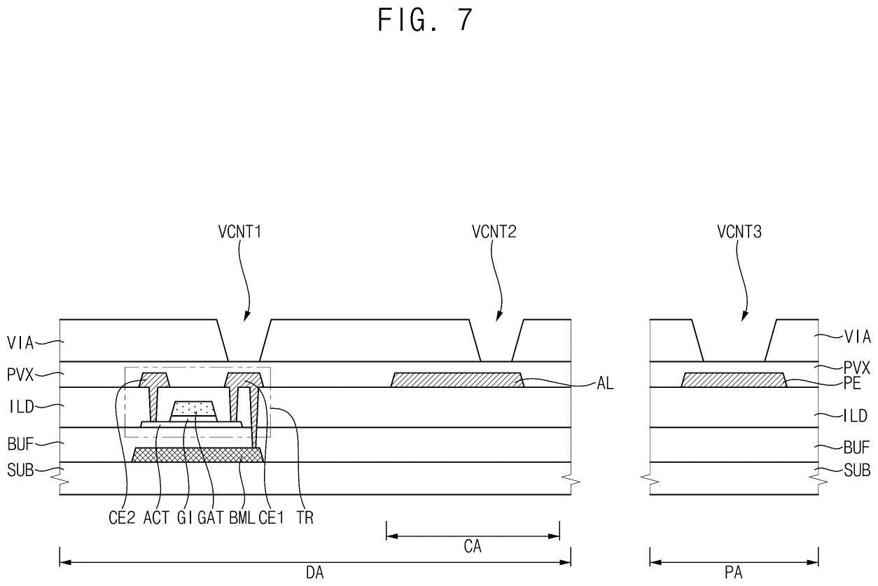

Referring to FIG. 7, in the display area DA, the first via contact hole VCNT1 may be formed by removing a portion of the organic insulating layer VIA to expose a portion of the protective layer PVX, and the second via contact hole VCNT2 exposing a portion of the protective layer PVX may be formed by removing another portion of the organic insulating layer VIA. The first via contact hole VCNT1 may overlap the first electrode CE1 in the plan view, and the second via contact hole VCNT2 may overlap the auxiliary power line AL in the plan view. In addition, the third via contact hole VCNT3 may be formed in the pad area PA by removing a portion of the organic insulating layer VIA to expose a portion of the protective layer PVX. The third via contact hole VCNT3 may overlap the pad electrode PE in the plan view.

That is, the first, second, and third via contact holes VCNT1, VCNT2, and VCNT3 may be formed simultaneously through the same process.

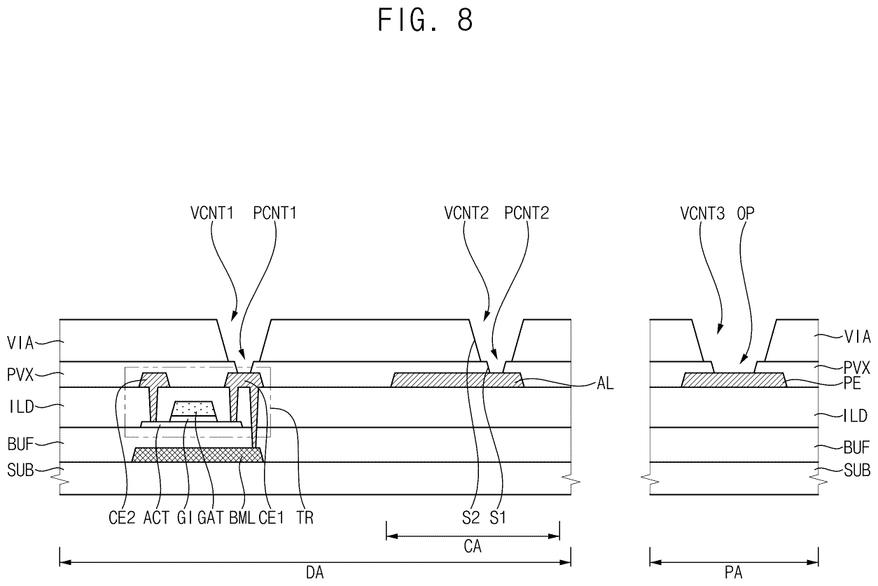

Referring to FIG. 8, in the display area DA, the first contact hole PCNT1 exposing at least a portion of the first electrode CE1 may be formed by removing a portion of the protective layer PVX overlapping the first via contact hole VCNT1 in the plan view using the organic insulating layer VIA as a mask. In addition, in the display area DA, the second contact hole PCNT2 exposing at least a portion of the auxiliary power line AL may be formed by removing another portion of the protective layer PVX overlapping the second via contact hole VCNT2 in the plan view using the organic insulating layer VIA as a mask. The first contact hole PCNT1 may be connected to the first via contact hole VCNT1 to expose at least a portion of the first electrode CE1, and the second contact hole PCNT2 may be connected to the second via contact hole VCNT2 to expose at least a portion of the auxiliary power line AL.

In the pad area PA, the opening OP exposing at least a portion of the pad electrode PE may be formed by a portion of the protective layer PVX overlapping the third via contact hole VCNT3 in the plan view using the organic insulating layer VIA as a mask. The opening OP may be connected to the third via contact hole VCNT3 to expose at least a portion of the pad electrode PE.

That is, the first contact hole PCNT1, the second contact hole PCNT2, and the opening OP may be formed simultaneously through the same process. In an embodiment, the first contact hole PCNT1, the second contact hole PCNT2, and the opening OP may be formed through a dry etching process. Accordingly, the first side surface S1 of the protective layer PVX exposed by the second contact hole PCNT2 may protrude further in the direction parallel to the substrate SUB than the second side surface S2 of the organic insulating layer VIA exposed by the second via contact hole VCNT2. For example, the second via contact hole VCNT2 and the second contact hole PCNT2 may form a stepped sidewall in the contact area CA.

Likewise, the side surface of the protective layer PVX exposed by the first contact hole PCNT1 may protrude further in the direction parallel to the substrate SUB than the side surface of the organic insulating layer VIA exposed by the first via contact hole VCNT1, and the side surface of the protective layer PVX exposed by the opening OP may protrude further in the direction parallel to the substrate SUB than the side surface of the organic insulating layer VIA exposed by the third via contact hole VCNT3. For example, the first via contact hole VCNT1 and the first contact hole PCNT1 may form a stepped sidewall in the display area DA, and the third via contact hole VCNT3 and the opening OP in the pad area PA.

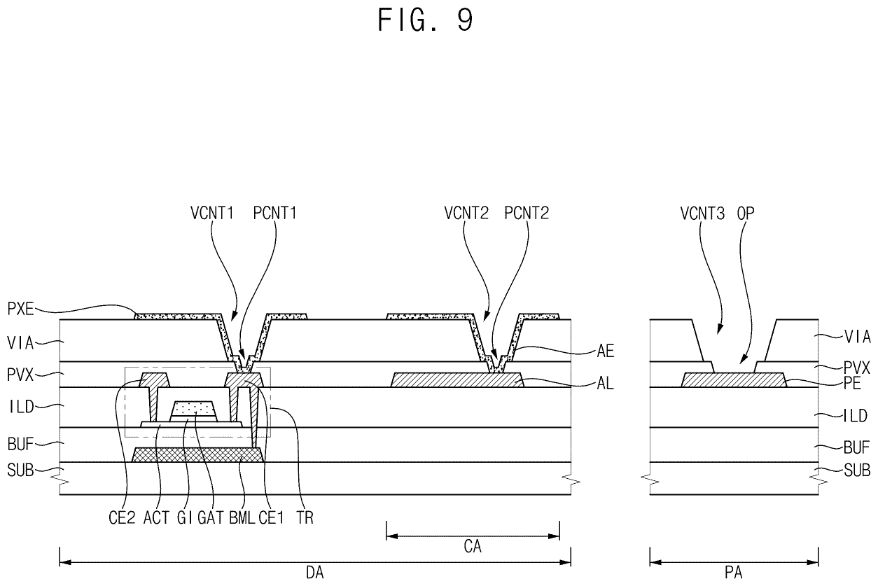

Referring to FIG. 9, a metal layer may be entirely formed on the organic insulating layer VIA. Next, the metal layer may be patterned to form the pixel electrode PXE and the auxiliary electrode AE in the display area DA. For example, the metal layer may be formed using metal, alloy, metal nitride, conductive metal oxide, or transparent conductive material.

That is, the pixel electrode PXE and the auxiliary electrode AE may be formed simultaneously through the same process. The pixel electrode PXE may be connected to the first electrode CE1 through the first contact hole PCNT1 and the first via contact hole VCNT1, and the auxiliary electrode AE may be connected to the auxiliary power line AL through the second contact hole PCNT2 and the second via contact hole VCNT2.

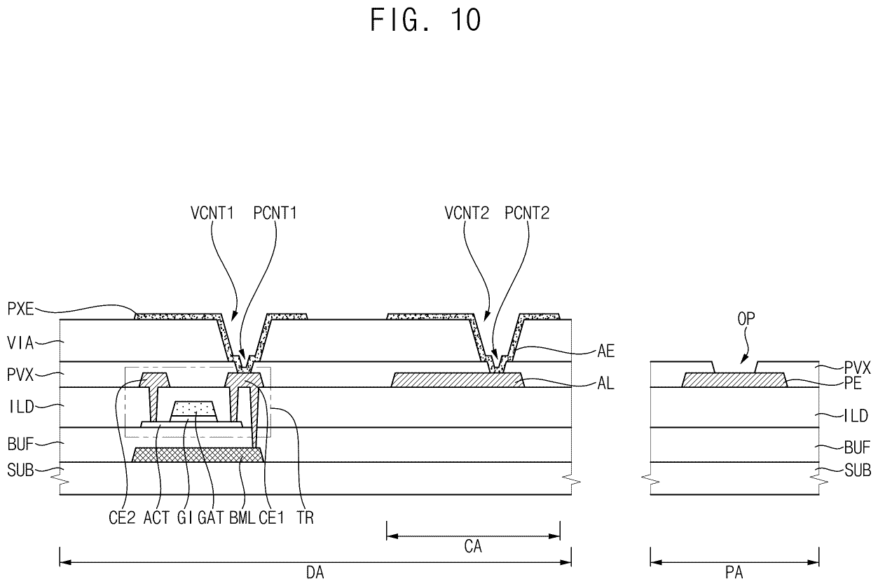

Referring to FIG. 10, a portion of the organic insulating layer VIA overlapping the pad area PA may be removed. That is, as a result, the organic insulating layer VIA may be formed only in the display area DA, and the organic insulating layer VIA may not be formed in the pad area PA.

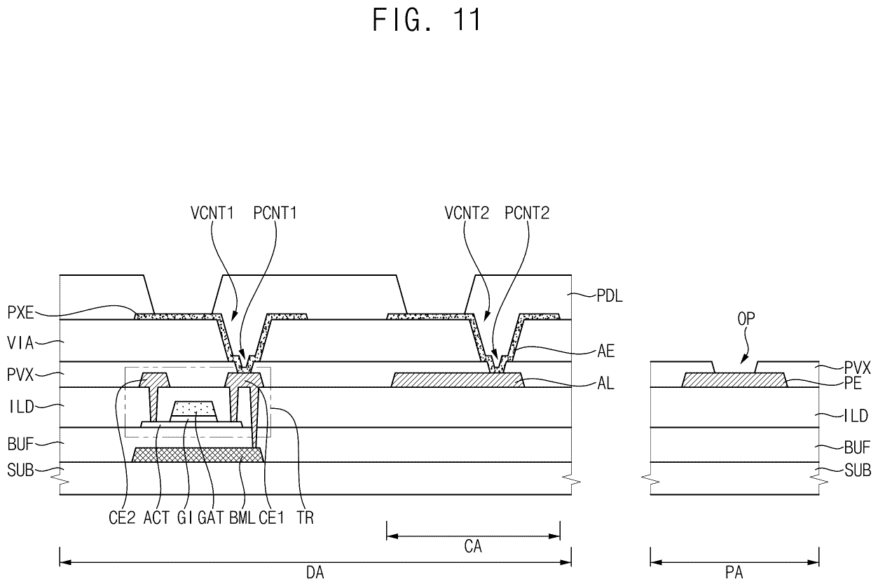

Referring to FIG. 11, the pixel defining layer PDL may be formed in the display area DA on the organic insulating layer VIA, the pixel electrode PXE, and the auxiliary electrode AE. The pixel defining layer PDL may expose at least a portion of each of the pixel electrode PXE and the auxiliary electrode AE. The pixel defining layer PDL may be disposed in the first contact hole PCNT1, the first via contact hole VCNT1, the second contact hole PCNT2, and the second contact hole VCNT2. In an embodiment, the pixel defining layer PDL may fill the first contact hole PCNT1, the first via contact hole VCNT1, the second contact hole PCNT2, and the second contact hole VCNT2. For example, the first contact hole PCNT1 and the second contact hole PCNT2 may be disposed below respective portions of the pixel defining layer PDL. The pixel defining layer PDL may be formed using inorganic materials and/or organic materials.

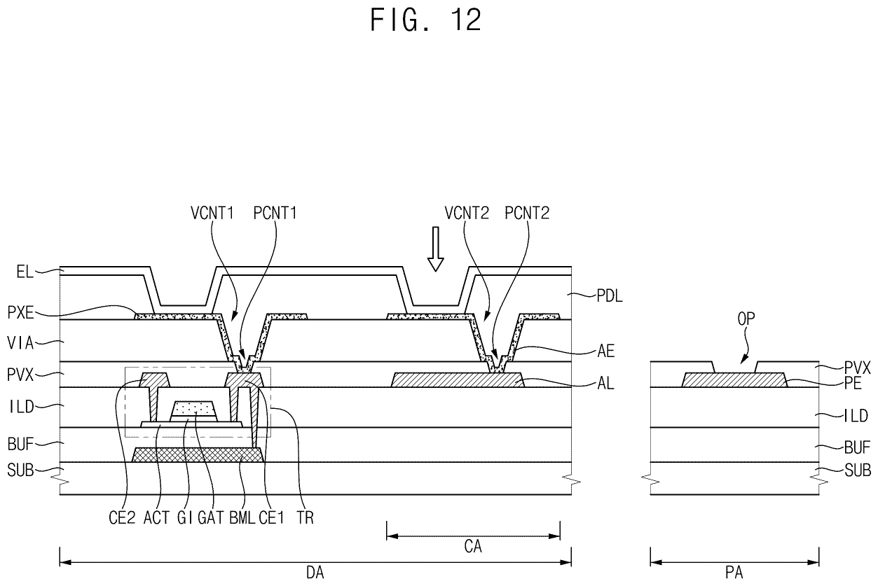

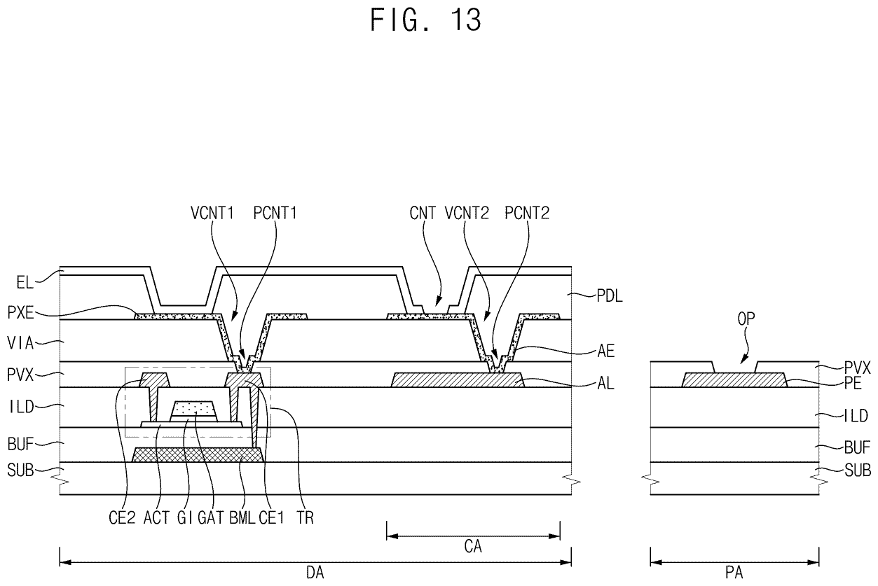

Referring to FIG. 12 and FIG. 13, the light-emitting layer EL may be disposed on the pixel defining layer PDL. The light-emitting layer EL may be disposed in the display area DA. For example, the light-emitting layer EL may be formed on the entire surface of a structure in the display area DA. The auxiliary electrode contact hole CNT exposing at least a portion of the auxiliary electrode AE may be formed in the contact area CA of the display area DA by removing a portion of the light-emitting layer EL. In an embodiment, the auxiliary electrode contact hole CNT may be formed through a laser drilling process. However, embodiments of the present disclosure are not limited thereto.

In an embodiment, the auxiliary electrode contact hole CNT may overlap the organic insulating layer VIA and the protective layer PVX in the plan view. That is, the portion of the auxiliary electrode AE exposed by the auxiliary electrode contact hole CNT may be spaced apart from the auxiliary power line AL when viewed the cross-section.

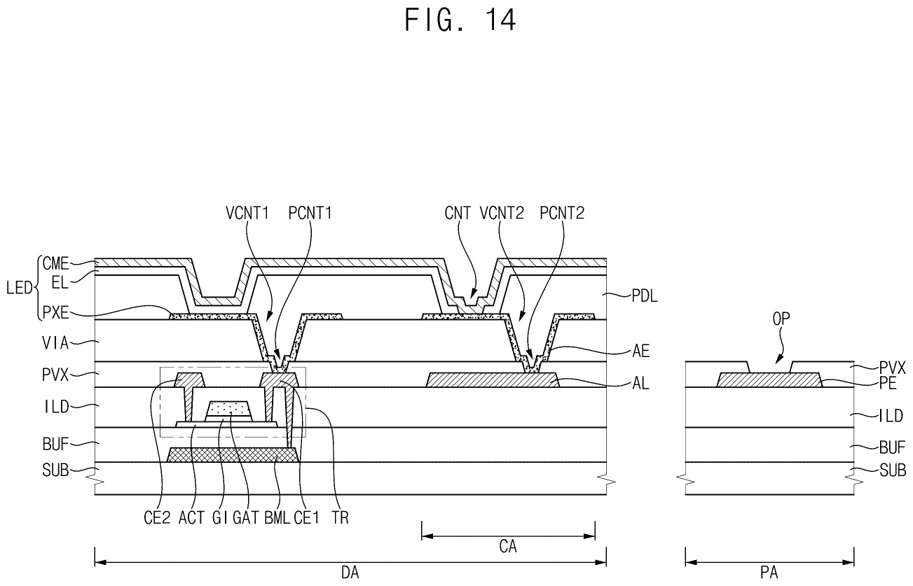

Referring to FIG. 14, the common electrode CME may be disposed on the light-emitting layer EL. The common electrode CME may be formed on the entire surface of a structure in the display area DA. The common electrode CME may be connected to the auxiliary electrode AE through a contact hole. For example, the common electrode CME may be formed using metal, alloy, metal nitride, conductive metal oxide, or transparent conductive material.

Accordingly, the light-emitting element LED including the pixel electrode PXE, the light-emitting layer EL, and the common electrode CME may be formed in the display area DA on the substrate SUB.

Referring again to FIG. 4, the encapsulation layer ENC may be formed on the common electrode CME. The encapsulation layer ENC may include at least one inorganic encapsulation layer and at least one organic encapsulation layer.

Accordingly, the display device 100 shown in FIG. 4 may be manufactured.

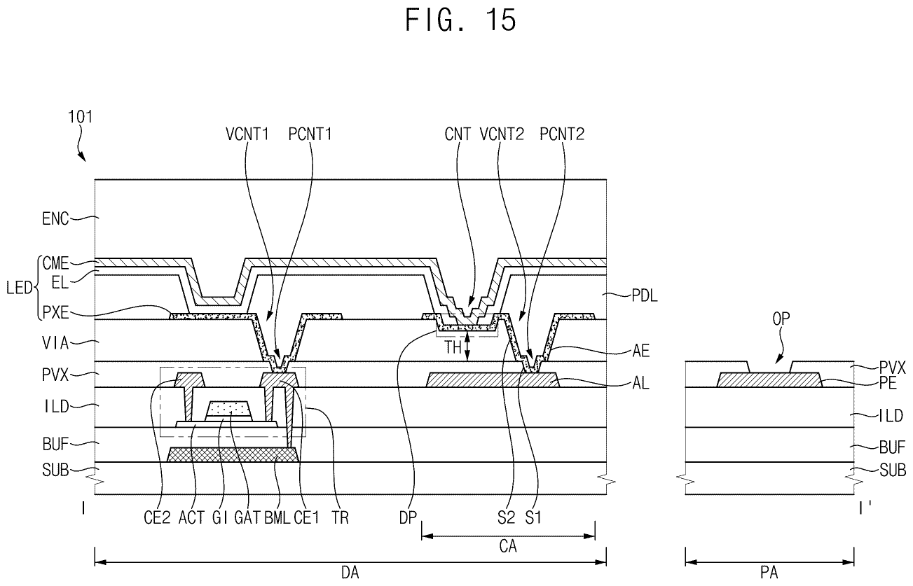

FIG. 15 is a cross-sectional view showing a display device according to an embodiment of the present disclosure.

Referring to FIG. 15, a display device 101 according to an embodiment of the present disclosure may include a substrate SUB, a lower metal layer BML, a buffer layer BUF, a gate insulating layer GI, a transistor TR, an interlayer insulating layer ILD, an auxiliary power line AL, a pad electrode PE, a protective layer PVX, an organic insulating layer VIA, an auxiliary electrode AE, a pixel defining layer PDL, the light-emitting element LED, and an encapsulation layer ENC. The display device 101 described with reference to FIG. 15 may be substantially the same as or similar to the display device 100 described with reference to FIG. 4. Therefore, hereinafter, overlapping descriptions may be omitted or simplified.

In an embodiment, an upper surface of the organic insulating layer VIA may include a depressed portion DP. The depressed portion DP may be depressed toward the auxiliary power line AL. The depressed portion DP may overlap an auxiliary electrode contact hole CNT penetrating a portion of the light-emitting layer EL in the plan view. For example, a height TH in the third direction DR3 between an upper surface of the protective layer PVX and a lower surface of the depression DP may be about 2000 angstroms (Å) to about 30000 Å. However, embodiments of the present disclosure are not limited thereto.

The depressed portion DP may be formed simultaneously with the first via contact hole VCNT1 and the second via contact hole VCNT2 through the same process. In an embodiment, the depressed portion DP may be formed by removing a portion of the upper surface of the organic insulating layer VIA so that the upper surface of the organic insulating layer VIA is depressed toward the auxiliary power line AL. The depressed portion DP may be formed by using a halftone mask.

The light-emitting layer EL and the common electrode CME disposed on a sidewall of the pixel defining layer PDL and the auxiliary electrode AE may have a stepped structure. For example, the light-emitting layer EL may be disposed on a surface of the auxiliary electrode AE above the depressed portion DP and a sidewall of the auxiliary electrode AE above the depressed portion DP. The light-emitting layer EL may be further disposed on at least a portion of an upper surface of the auxiliary electrode AE adjacent to the depressed portion DP and above an upper surface of the organic insulating layer VIA. For example, The light-emitting layer EL and the common electrode CME disposed on a sidewall of the pixel defining layer PDL and the auxiliary electrode AE may have a multi-step structure.

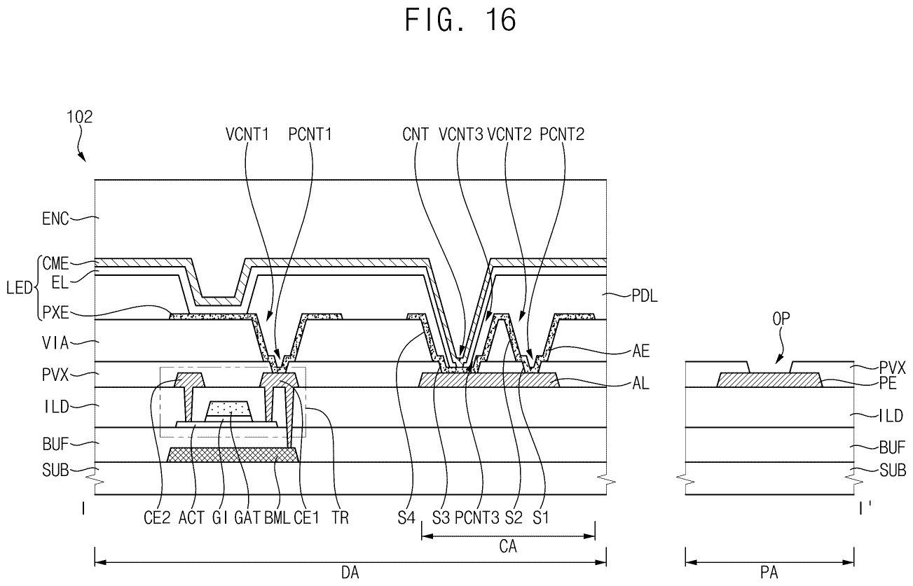

FIG. 16 is a cross-sectional view showing a display device according to an embodiment of the present disclosure.

Referring to FIG. 16, a display device 102 according to an embodiment of the present disclosure may include a substrate SUB, a lower metal layer BML, a buffer layer BUF, a gate insulating layer GI, a transistor TR, an interlayer insulating layer ILD, an auxiliary power line AL, a pad electrode PE, a protective layer PVX, an organic insulating layer VIA, an auxiliary electrode AE, a pixel defining layer PDL, the light-emitting element LED, and an encapsulation layer ENC. The display device 102 described with reference to FIG. 16 may be substantially the same as or similar to the display device 100 described with reference to FIG. 4. Descriptions overlapping with those of the display device 100 described with reference to FIG. 4 may be omitted or simplified.

In an embodiment, in the display area DA, a first contact hole PCNT1 exposing at least a portion of the first electrode CE1 and a second contact hole PCNT2 exposing at least a portion of the auxiliary power line AL may be defined in protective layer PVX. In other words, each of the first contact hole PCNT1 and the second contact hole PCNT1 may be defined by penetrating a portion of the protective layer PVX.

In an embodiment, a first via contact hole VCNT1 connected to the first contact hole PCNT1 and exposing the first contact hole PCNT1 may be defined in the organic insulating layer VIA. The first via contact hole VCNT1 may expose at least a portion of the first electrode CE1 together with the first contact hole PCNT1. In other words, the first via contact hole VCNT1 may be defined by penetrating a portion of the organic insulating layer VIA.

Likewise, in an embodiment, a second via contact hole VCNT2 connected to the second contact hole PCNT2 and exposing the second contact hole PCNT2 may be defined in the organic insulating layer VIA. The second via contact hole VCNT2 may expose at least a portion of the auxiliary power line AL together with the second contact hole PCNT2. In other words, the second via contact hole VCNT2 may be defined by penetrating a portion of the organic insulating layer VIA.

In an embodiment, in the contact area CA, a third contact hole PCNT3 exposing at least a portion of the auxiliary power line AL may be defined in the protective layer PVX. In other words, the third contact hole PCNT3 may be defined by penetrating a portion of the protective layer PVX. In addition, a third via contact hole VCNT3 connected to the third contact hole PCNT3 and exposing the third contact hole PCNT3 may be defined in the organic insulating layer VIA. The third via contact hole VCNT3 may expose at least a portion of the auxiliary power line AL together with the third contact hole PCNT3. In other words, the third via contact hole VCNT3 may be formed by penetrating a portion of the organic insulating layer VIA.

In an embodiment, the third contact hole PCNT3 and the third via contact hole VCNT3 may overlap an auxiliary electrode contact hole CNT penetrating a portion of the light-emitting layer EL in the plan view. That is, the auxiliary electrode contact hole CNT may not overlap the protective layer PVX and the organic insulating layer VIA in the plan view.

In an embodiment, a first side surface S1 of the protective layer PVX exposed by the second contact hole PCNT2 may protrude further in a direction parallel to the substrate SUB than a second side surface S2 of the organic insulating layer VIA exposed by the second via contact hole VCNT2. Likewise, a third side surface S3 of the protective layer PVX exposed by the third contact hole PCNT3 may protrude further in the direction parallel to the substrate SUB than a fourth side surface S4 of the organic insulating layer VIA exposed by the third via contact hole VCNT3. However, embodiments of the present disclosure are not limited thereto.

The auxiliary electrode AE disposed in the same layer as the pixel electrode PXE may be disposed in the display area DA on the organic insulating layer VIA. The auxiliary electrode AE may define a contact area CA in the display area DA. The auxiliary electrode AE may be connected to the auxiliary power line AL through the second via contact hole VCNT2 and the second contact hole PCNT2. In addition, in an embodiment, the auxiliary electrode AE may be connected to the auxiliary power line AL through the third via contact hole VCNT3 and the third contact hole PCNT3. That is, the auxiliary electrode AE may directly contact the auxiliary power line AL through the second contact hole PCNT2 and the second via contact hole VCNT2, and may directly contact the auxiliary power line AL through the third contact hole PCNT3 and the third via contact hole VCNT3.

The pixel defining layer PDL may be disposed in the display area DA on the organic insulating layer VIA. The pixel defining layer PDL may fill the first via contact hole VCNT1 and the first contact hole PCNT1, and may be disposed in the second via contact hole VCNT2 and the second contact hole PCNT2. For example, the pixel defining layer PDL may fill the first via contact hole VCNT1 and the first contact hole PCNT1, and may fill the second via contact hole VCNT2 and the second contact hole PCNT2.

In an embodiment, the pixel defining layer PDL may extend to the inside of the third contact hole PCNT3 and the third via contact hole VCNT3. Specifically, the pixel defining layer PDL may extend to the inside of the third contact hole PCNT3 and the third via contact hole VCNT3, and cover the third side surface S3 of the protective layer PVC exposed by the third contact hole PCNT3 and the fourth side surface S4 of the organic insulating layer VIA exposed by the third via contact hole VCNT3.

In an embodiment, the pixel defining layer PDL may expose at least a portion of the auxiliary electrode AE inside the third contact hole PCNT3. However, embodiments of the present disclosure are not limited thereto. For example, the pixel defining layer PDL may entirely contact the auxiliary electrode AE inside the third contact hole PCNT3.

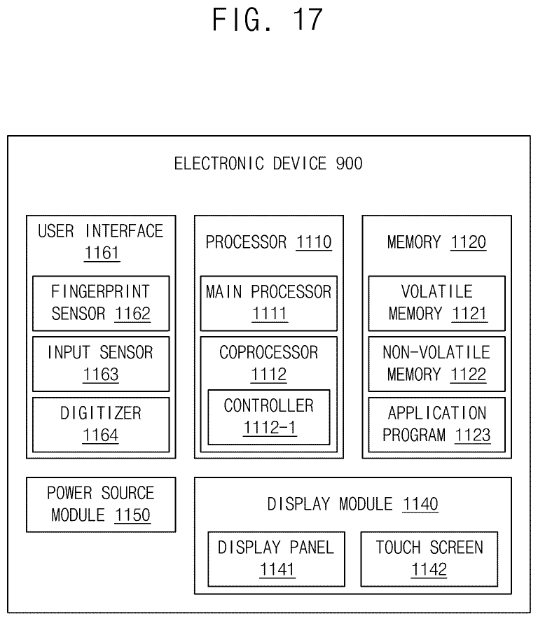

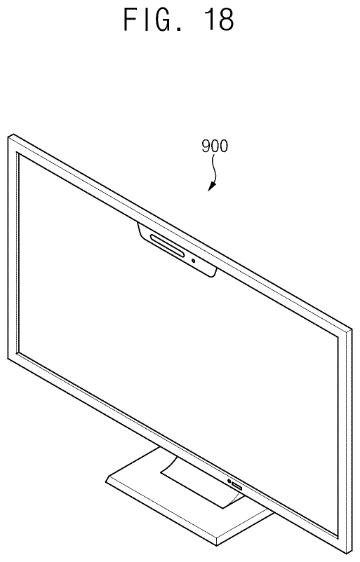

FIG. 17 is a block diagram showing an electronic device including the display device of FIG. 1. FIG. 18 is a view illustrating an example in which the electronic device of FIG. 17 is implemented as a television.

Referring to FIG. 17 and FIG. 18, in an embodiment, the electronic device 900 according to one embodiment of the present invention may output various information (e.g., images, text, music, etc.) through a display module 1140, which, for example, may correspond to the display device 100 shown in FIG. 4. When a processor 1110 executes an application stored in a memory 1120, the display module 1140 may provide application information to a user through a display panel 1141.

In some embodiments, the electronic device 900 may be configured as a smartphone, camera, smart TV, monitor, smartwatch, tablet, automotive display, or AR/VR headset. For example, the electronic device 900 may be a smartphone including a touch-sensitive display area DA for interaction and a non-display area NDA including sensors and circuits for enhanced functionality. For example, the electronic device 900 may be a television or monitor including a large display area DA for high-resolution video playback and a non-display area NDA incorporating driving circuits or connectivity modules for external inputs. For example, the electronic device 900 may be a smartwatch including a display area DA optimized for compact and high-clarity visuals and a non-display area NDA integrating biometric sensors for health monitoring. In some cases, the electronic device 900 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 900, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 900 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the display device 100 shown in FIG. 4.

The user interface 1161 serves as the interaction medium between a user and the electronic device 900. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 900.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the display device 100 shown in FIG. 4.

The power source module 1150 may supply power to the components of the electronic device 900. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

The present disclosure can be applied to various display devices which can be equipped with a display device. For example, the present disclosure can be applied to high-resolution smartphones, mobile phones, smart pads, smart watches, tablet PCs, vehicle navigation systems, televisions, computer monitors, or laptops.

The foregoing is illustrative of embodiments and is not to be construed as limiting thereof. Although example embodiments have been described, those skilled in the art will readily appreciate that many modifications are possible without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limiting, and that modifications to embodiments, as well as other embodiments, are intended to be included within the scope of the appended claims.

What is claimed is:

1. A display device comprising:
an auxiliary power line disposed in a display area on a substrate and electrically connected to a voltage supply part;
an organic insulating layer disposed on the auxiliary power line;
a pixel electrode disposed in the display area on the organic insulating layer;
an auxiliary electrode disposed in a same layer as the pixel electrode in the display area and connected to the auxiliary power line;
a light-emitting layer disposed in the display area and on the pixel electrode and the auxiliary electrode; and
a common electrode disposed in the display area and on the light-emitting layer and connected to the auxiliary electrode through an auxiliary electrode contact hole, the auxiliary electrode contact hole penetrating a portion of the light-emitting layer and the auxiliary electrode contact hole overlapping the organic insulating layer in a plan view.

2. The display device of claim 1, wherein a portion of the auxiliary electrode exposed by the auxiliary electrode contact hole penetrating the portion of the light-emitting layer is spaced apart from the auxiliary power line when viewed a cross-section.

3. The display device of claim 1, further comprising:
a protective layer disposed between the substrate and the organic insulating layer and covering the auxiliary power line,
wherein the auxiliary electrode is connected to the auxiliary power line through a second via contact hole penetrating a portion of the organic insulating layer and a second contact hole penetrating a portion of the protective layer and overlapping the second via contact hole.

4. The display device of claim 3, wherein the auxiliary electrode contact hole penetrating the portion of the light-emitting layer overlaps the protective layer in the plan view.

5. The display device of claim 3, further comprising:
a pixel defining layer disposed on the organic insulating layer and exposing at least a portion of the pixel electrode and a portion of the auxiliary electrode,
wherein the pixel defining layer fills the second via contact hole and the second contact hole penetrating the portion of the protective layer.

6. The display device of claim 5, wherein a first side surface of the protective layer exposed by the second contact hole penetrating the portion of the protective layer protrudes more in a direction parallel to the substrate than a second side surface of the organic insulating layer exposed by the second via contact hole.

7. The display device of claim 1, further comprising:
an active layer disposed in the display area on the substrate;
a gate electrode disposed on the active layer and overlapping a channel region of the active layer;
a first electrode connected to a source region of the active layer; and
a second electrode disposed in a same layer as the first electrode and connected to a drain region of the active layer.

8. The display device of claim 7, wherein the auxiliary power line is disposed in a same layer as the first electrode and the second electrode.

9. The display device of claim 7, wherein the auxiliary power line is disposed in a same layer as the gate electrode.

10. The display device of claim 1, wherein an upper surface of the organic insulating layer includes a depressed portion depressed toward the auxiliary power line, and
the depressed portion overlaps the auxiliary electrode contact hole penetrating the portion of the light-emitting layer in the plan view.

11. A display device comprising:
an auxiliary power line disposed in a display area on a substrate and electrically connected to a voltage supply part;
an organic insulating layer disposed on the auxiliary power line;
a pixel electrode disposed in the display area on the organic insulating layer;
an auxiliary electrode disposed in a same layer as the pixel electrode in the display area and connected to the auxiliary power line;
a light-emitting layer disposed in the display area and on the pixel electrode and the auxiliary electrode;
a common electrode disposed in the display area the display area and on the light-emitting layer and connected to the auxiliary electrode through an auxiliary contact hole penetrating a portion of the light-emitting layer; and
a pixel defining layer disposed on the organic insulating layer, exposing at least a portion of the pixel electrode and at least a portion of the auxiliary electrode, and extending to an inside of a third via contact hole, the third via contact hole penetrating a portion of the organic insulating layer and overlapping the auxiliary contact hole in a plan view.

12. The display device of claim 11, further comprising:
a protective layer covering the auxiliary power line between the substrate and the organic insulating layer,
wherein the auxiliary electrode is connected to the auxiliary power line through the third via contact hole and a second via contact hole penetrating a portion of the organic insulating layer, and
wherein a second contact hole penetrates a portion of the protective layer and exposes the second via contact hole, and a third contact hole penetrates a portion of the protective layer and exposes the third via contact hole.

13. The display device of claim 12, wherein the pixel defining layer extends to an inside of the third via contact hole and the third contact hole.

14. The display device of claim 13, wherein the pixel defining layer exposes at least a portion of the auxiliary electrode overlapping the third contact hole in a plan view.

15. The display device of claim 12, wherein the pixel defining layer fills the second via contact hole and the second contact hole.

16. The display device of claim 12, wherein a first side surface of the protective layer exposed by the third contact hole protrudes further in a direction parallel to the substrate than a second side surface of the organic insulating layer exposed by the third via contact hole.

17. The display device of claim 12, wherein a first side surface of the protective layer exposed by the second contact hole protrudes further in a direction parallel to the substrate than a second side surface of the organic insulating layer exposed by the second via contact hole.

18. An electronic device comprising:
a display device includes:
an auxiliary power line disposed in a display area on a substrate and electrically connected to a voltage supply part;
an organic insulating layer disposed on the auxiliary power line;
a pixel electrode disposed in the display area on the organic insulating layer;
an auxiliary electrode disposed in a same layer as the pixel electrode in the display area and connected to the auxiliary power line;
a light-emitting layer disposed in the display area and on the pixel electrode and the auxiliary electrode; and
a common electrode disposed in the display area and on the light-emitting layer and connected to the auxiliary electrode through an auxiliary electrode contact hole, the auxiliary electrode contact hole penetrating a portion of the light-emitting layer and the auxiliary electrode contact hole overlapping the organic insulating layer in a plan view; and
a processor which controls the display device.

19. The electronic device of claim 18, wherein a portion of the auxiliary electrode exposed by the auxiliary electrode contact hole penetrating the portion of the light-emitting layer is spaced apart from the auxiliary power line when viewed a cross-section.

20. The electronic device of claim 18, wherein the display device further includes:
a protective layer disposed between the substrate and the organic insulating layer and covering the auxiliary power line,
wherein the auxiliary electrode is connected to the auxiliary power line through a second via contact hole penetrating a portion of the organic insulating layer and a second contact hole penetrating a portion of the protective layer and overlapping the second via contact hole.
